(19) United States
(12) Patent Application Publication
(10) Pub. No.: US 2020/0203205 A1
(43) Pub. Date: Jun. 25, 2020

(54) ELECTROSTATIC CHUCK

(71) Applicant: XIA TAI XIN SEMICONDUCTOR (QING DAO) LTD., Qingdao (CN)

(72) Inventor: YOUNG-WOO LEE, Singapore (SG)

(21) Appl. No.: 16/663,378

(22) Filed: Oct. 25, 2019

Related U.S. Application Data
(60) Provisional application No. 62/779,495, filed on Dec. 14, 2018.

(51) Int. Cl. H01L 21/683; H01L 21/67

(52) U.S. Cl. CPC H01L 21/6833; H01L 21/67069; H01L 21/67103

(57) ABSTRACT

An electrostatic chuck (ESC) structure is disclosed. The ESC includes a dielectric structure, an electrode, and a metal sheet. The electrode and the metal sheet are embedded in the dielectric structure. The fluctuation of heat distribution on the ESC is one source of problems during implementation of a process. The metal sheet is used to provide equal distribution of heat on the ESC.

### CROSS-REFERENCES TO RELATED APPLICATIONS

This application claims the benefit of U.S. Provisional Patent Application No. 62/779,495 filed on Dec. 14, 2018, which is hereby incorporated by reference herein and made a part of specification.

### BACKGROUND

### 1. Field

The present disclosure generally relates to electrostatic chuck, and more particularly, electrostatic chuck having embedded metal sheet in addition to an electrode.

### 2. Related Art

Electrostatic chucks (ESC) are widely utilized in plasma- and vacuum-based semiconductor processes. Temperature control is one important aspect of an ESC. There is a need to improve the temperature control of the ESC to increase yield of the semiconductor process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a sectional view of an electrostatic chuck (ESC) according to some embodiments of the present disclosure;

FIG. 2 illustrates a sectional view of an ESC with an embossed metal sheet according to some other embodiments of the present disclosure;

FIG. 3 illustrates a flowchart of a method of forming an ESC according to some embodiments of the present disclosure;

FIG. 4 illustrates a flowchart of a method of forming an ESC according to some other embodiments of the present disclosure; and

FIG. 5 illustrates a top view of the electrostatic chuck (ESC) according to some embodiments of the present disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

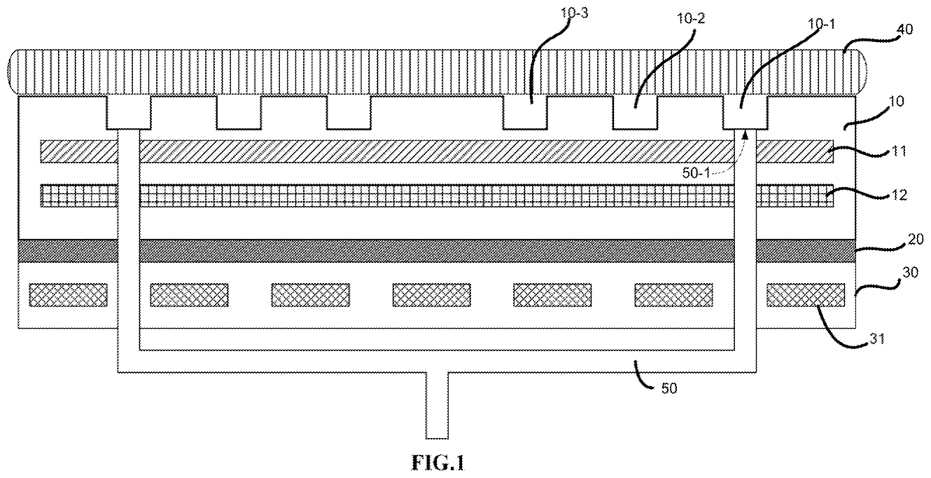

FIG. 1 illustrates cross-sectional view from a side of an electrostatic chuck (ESC) with a metal sheet according to some embodiment of the present disclosure. The ESC comprises a dielectric structure 10, an electrode 12, and a metal sheet 11. The dielectric structure 10 has a top surface. A top surface of the dielectric structure comprises a plurality of annular protrusions and a plurality of interposing annular depressions 10-1, 10-2, and 10-3 defined there-between.

The dielectric structure 10 may be made of at least one dielectric material including aluminum oxide, aluminum nitride, silicon carbide, carbon nitride, zirconia, yttria, and magnesia. The electrode 12 is embedded in the dielectric structure 10. The electrode 12 may be made of at least one metal including copper, tungsten, aluminum, nickel, chrome, platinum, tin, molybdenum, magnesium, and palladium.

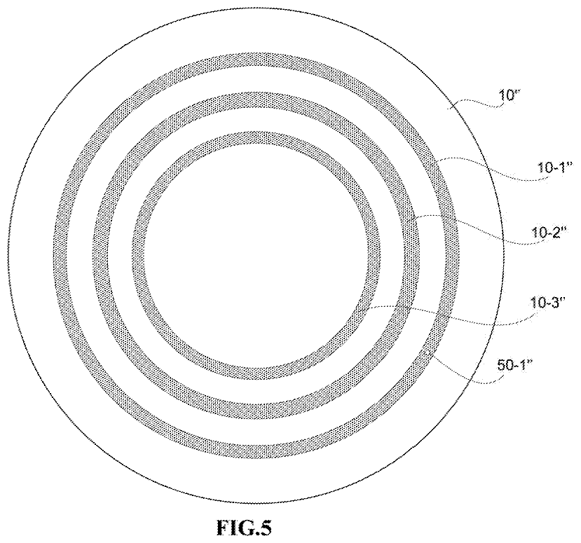

As illustrated by the exemplary embodiment shown in FIG. 1, the metal sheet 11 is embedded in the dielectric structure 10 and is disposed between the electrode 12 and the top surface of the dielectric structure 10. The metal sheet 11 may include a continuous solid metal sheet. In some embodiments, metal sheet 11 is a flat metal sheet. In some embodiments, at least one through hole 50-1 formed on a projected area of at least one of the plurality of annular depressions 10-1, 10-2, and 10-3 on the metal sheet 11 (e.g., as illustrated by a through hole 50-1″ and the plurality of annular depressions 10-1″, 10-2″, and 10-3″ in FIG. 5).

The metal sheet 11 is electrically floating with respect to the electrode 12. However, it should be mentioned that in the illustrated embodiment, although the metal sheet 11 is electrically floating with respect to the electrode 12, the metal sheet 11 still has some influence to the chucking and dechucking operation of the ESC. In the instant embodiment, a thermal conductivity of the metal sheet is configured to be greater than a thermal conductivity of dielectric structure 10 and a thermal conductivity of the electrode 12. In some embodiments, a material having thermal conductivity greater than 400 W/mK is utilized in forming the metal sheet 11. In some embodiments, the metal sheet is made of metal material such as silver, which generally possesses thermal conductivity of about 406 W/mK. A thickness of the metal sheet may range from 10 nm to 100 nm.

In some embodiments, when the metal sheet 11 has a high thermal expansion coefficient compared to the thermal expansion coefficient of the dielectric structure 10, implementation of metal sheet 11 having a thickness may cause micro cracks in the dielectric structure 10 when heated. Accordingly, the metal sheet may be made to be thin enough to prevent micro cracks on the dielectric structure 10 that can be caused by the expansion of the metal sheet 11 during processes using high temperature. A distance between the metal sheet 11 and a portion of the top surface of the dielectric structure 10 closest to the metal sheet ranges from about 10 μm to 200 μm.

In some embodiments, the ESC further includes a heating plate 30 and a bonding layer 20. The heating plate 30 is disposed under the dielectric structure 10. The heating plate 30 includes heating element 31 configured to generate heat as needed. The bonding layer 20 is disposed between the heating plate 30 and the dielectric structure 10. The bonding layer 20 is made of at least one bonding material including a thermoplastic polyimide film (TPI), an epoxy thermal press bonding sheet, a low melting point metal, a low melting point metal alloy, and a eutectic alloy. In some embodiments, the ESC further includes a channel 50. The channel 50 is used to deliver coolants to the interposing annular depressions 10-1, 10-2, and 10-3 on the top surface of the dielectric structure 10. The coolant may be a heat exchange gas including Helium. The channel 50 passes through the though holes of dielectric structure 10 and the metal sheet 11. The though holes of dielectric structure 10 and the metal sheet 11 are aligned to each other.

During operation of the ESC, a workpiece 40 is disposed on the ESC. In some embodiments, the workpiece 40 is a wafer or a substrate made of any suitable material that can withstand the process being performed. The workpiece 40 is in physical contact with the dielectric structure 10. Static electricity is induced to the top surface of the dielectric structure 10 to enable chucking of the workpiece 40. During chucking, the electrode 12 may be positively charged to attract the workpiece 40. The resistance of the metal sheet 11 is low enough to have no substantial effect on the chucking capability of the ESC. When the electrode 12 is turned off, the top surface of the dielectric structure 10 is discharged at a time to enable dismounting of object (e.g., declamping time). When the charge is removed from the electrode 12, the metal sheet 11 attracts the negative charge from the surface of the dielectric to enable a faster dismounting of the workpiece 40.

In an exemplary embodiment of a plasma etching process, the surface temperature of the workpiece 40 depends on the temperature of the ESC, the ion density, ion energy and the exothermicity of the etching reaction. Surface temperature of the workpiece 40 influences etching processes including the reaction probabilities of incident species, the vapor pressure of etch products, and the re-deposition of reaction products on the workpiece 40 surface. Sudden changes in the plasma condition during processing may cause non-uniformity of the surface temperature of the workpiece 40 and, in turn, loss in critical dimension. Thus, control of the surface temperature of the workpiece 40 is important. Having the metal sheet 11 in close proximity to the top surface of the ESC improves the heat dispersion on the ESC.

The metal sheet 11 is able to pull heat from areas having higher temperature and dispersing the heat throughout the ESC and the workpiece 40 for even heat distribution. The metal sheet 11 is configured to equalize the temperature throughout the wafer. In some embodiments, some portion of the workpiece 40 may have higher temperature than the ideal temperature. The metal sheet 11 helps disperse the temperature to other portion of the workpiece 40 to reach equilibrium in temperature. In other embodiments, some portion of the workpiece 40 has lower temperature than the ideal temperature upon contact with a coolant. The metal sheet 11 helps disperse the heat to the cooler portion of the workpiece 40 to reach equilibrium in temperature.

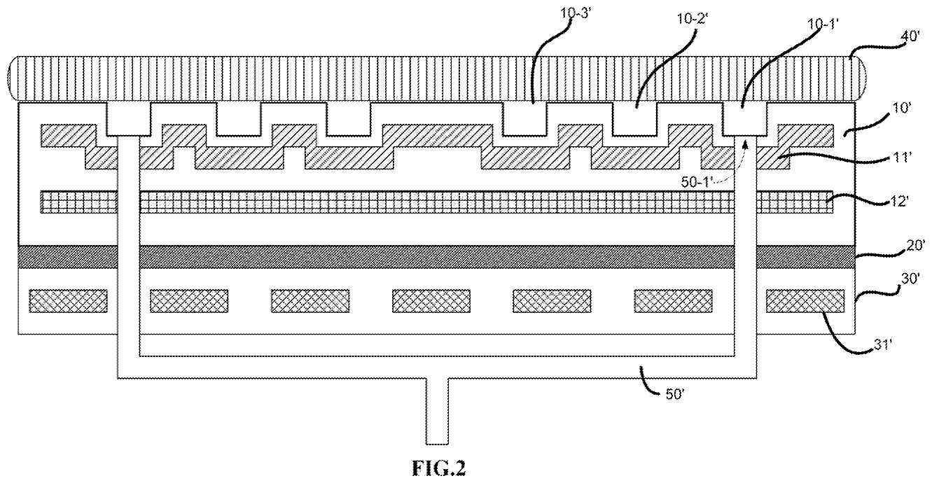

FIG. 2 illustrates an electrostatic chuck (ESC) with an embossed metal sheet according to some embodiment of the present disclosure. The ESC comprises a dielectric structure 10′, an electrode 12′, and a metal sheet 11′. The dielectric structure 10′ has a top surface. A top surface of the dielectric structure comprises a plurality of annular protrusions and a plurality of interposing annular depressions 10-1′, 10-2′, and 10-3′ defined there-between. The dielectric structure 10′ is made of at least one dielectric material including aluminum oxide, aluminum nitride, silicon carbide, carbon nitride, zirconia, yttria, and magnesia. The electrode 12′ is embedded in the dielectric structure 10′. The electrode 12′ is made of at least one metal including copper, tungsten, aluminum, nickel, chrome, platinum, tin, molybdenum, magnesium, and palladium.

The metal sheet 11′ is embedded in the dielectric structure 10′ and is disposed between the electrode 12′ and the top surface of the dielectric structure 10′. In some embodiments, the metal sheet 11′ is a continuous solid metal sheet. The metal sheet 11′ is an embossed sheet having protrusions and depressions conforming to the plurality of annular protrusions and the plurality of annular depressions 10-1′, 10-2′, and 10-3′ of the top surface of the dielectric structure 10′. The metal sheet 11′ is arranged with substantially uniform depth from the top surface of the dielectric structure 10′. In some embodiments, at least one through hole 50-1′ formed on a projected area of at least one of the plurality of annular depressions 10-1′, 10-2′, and 10-3′ on the metal sheet 11′.

In some embodiments, the metal sheet 11′ is electrically floating with respect to the electrode 12′. However, it should be mentioned that although the metal sheet 11′ is electrically floating with respect to the electrode 12′, the metal sheet 11′ still has some influence to the chucking and dechucking operation of the ESC. the A thermal conductivity of the metal sheet is greater than a thermal conductivity of dielectric structure 10′ and a thermal conductivity of the electrode 12′. The thermal conductivity of the metal sheet 11′ is greater than 400 W/mK. In some embodiments, the metal sheet is made of metal including a silver metal sheet having a thermal conductivity of 406 W/mK. A thickness of the metal sheet ranges from 10 nm to 100 nm.

In some embodiments, when the metal sheet 11′ has a high thermal expansion coefficient, implementation of metal sheet 11 having a thickness may cause micro cracks in the dielectric structure 10′ when heated. The metal sheet is made to be thin enough to prevent micro cracks on the dielectric structure 10′ that can be caused by the expansion of the metal sheet 11′ during processes using high temperature. In some embodiments distance between the metal sheet 11′ and a portion of the top surface of the dielectric structure 10′ closest to the metal sheet ranges from about 10 μm to 200 μm.

In some embodiments, the ESC further includes a heating plate 30′ and a bonding layer 20′. The heating plate 30′ is disposed under the dielectric structure 10′. The heating plate 30′ includes heating element 31′ configured to generate heat as needed. The bonding layer 20′ is disposed between the heating plate 30′ and the dielectric structure 10′. The bonding layer 20′ is made of at least one bonding material including a thermoplastic polyimide film (TPI), an epoxy thermal press bonding sheet, a low melting point metal, a low melting point metal alloy, and a eutectic alloy. In some embodiments, the ESC further includes a channel 50′. The channel 50′ is used to deliver coolants to the interposing annular depressions 10-1′, 10-2′, and 10-3′ on the top surface of the dielectric structure 10′. The coolant may be a heat exchange gas including Helium. The channel 50′ passes through the though holes of dielectric structure 10′ and the metal sheet 11′. The though holes of dielectric structure 10′ and the metal sheet 11′ are aligned to each other.

During the operation of the ESC, a workpiece 40′ is disposed on the ESC. In some embodiments, the workpiece 40′ is a wafer or a substrate made of any suitable material that can withstand the process being performed. The workpiece 40′ is in physical contact with the dielectric structure 10′. Static electricity is induced to the top surface of the dielectric structure 10′ to enable chucking of the workpiece 40′. During chucking, the electrode 12′ is positively charged to attract the workpiece 40′. The resistance of the metal sheet 11′ is low enough to have no substantial effect on the chucking capability of the ESC. When the electrode 12′ is turned off, the top surface of the dielectric structure 10′ is discharged at a time to enable dismounting of object (e.g., declamping time). When the charge is removed from the electrode 12′, the metal sheet 11′ attracts the negative charge from the surface of the dielectric to enable a faster dismounting of the workpiece 40′.

In an exemplary embodiment of a plasma etching process, the surface temperature of the workpiece 40′ depends on the temperature of the ESC, the ion density, ion energy and the exothermicity of the etching reaction. Surface temperature of the workpiece 40′ influences etching processes including the reaction probabilities of incident species, the vapor pressure of etch products, and the re-deposition of reaction products on the workpiece 40′ surface. Sudden changes in the plasma condition during processing may cause non-uniformity of the surface temperature of the workpiece 40′ and, in turn, loss in critical dimension. Thus, control of the surface temperature of the workpiece 40′ is important. Having the metal sheet 11′ in close proximity to the top surface of the ESC improves the heat dispersion on the ESC. The metal sheet 11′ is able to pull heat from areas having higher temperature and dispersing the heat throughout the ESC and the workpiece 40 for even heat distribution.

The metal sheet 11′ is configured to equalize the temperature throughout the wafer. In some embodiments, some portion of the workpiece 40′ may have higher temperature than the ideal temperature. The metal sheet 11′ helps disperse the temperature to other portion of the workpiece 40′ to reach equilibrium in temperature. In other embodiments, some portion of the workpiece 40′ has lower temperature than the ideal temperature upon contact with coolant. The metal sheet 11′ helps disperse the heat to the cooler portion of the workpiece 40′ to reach equilibrium in temperature.

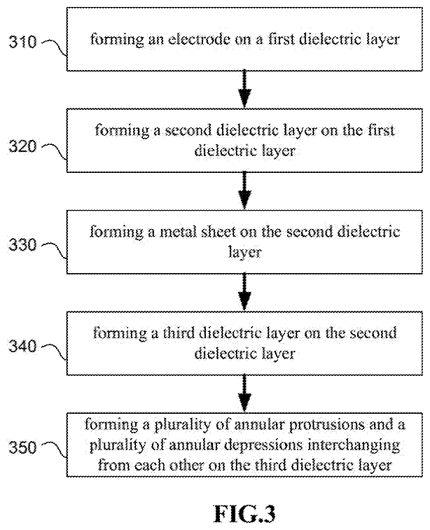

FIG. 3 illustrates a flowchart of a method of forming ESC according to some embodiments of the present disclosure. The method comprises forming an electrode on a first dielectric layer (310), forming a second dielectric layer on the first dielectric layer (320), forming a metal sheet on the second dielectric layer (330), forming a third dielectric layer on the second dielectric layer (340), and forming a plurality of annular protrusions and a plurality of annular depressions interchanging from each other on the third dielectric layer (350). A dielectric structure is formed by the first dielectric layer, the second dielectric layer, and the third dielectric layer. The second dielectric layer is encapsulating the electrode. The third dielectric layer is encapsulating the metal sheet. In some embodiments, the metal sheet and the electrode are formed through lamination.

In some embodiments, the method further comprises etching the second dielectric layer to for a plurality of annular depressions. An embossed surface of the metal sheet conforms to the annular depressions of the second dielectric layer and the plurality of annular depressions of the top surface of the dielectric structure is formed with respect to the embossed surface of the metal sheet.

The metal sheet is a solid continuous metal sheet. In some embodiments, metal sheet is a flat metal sheet. In other embodiments, the metal sheet is an embossed sheet having protrusions and depressions conforming to the plurality of annular protrusions and the plurality of annular depressions of the top surface of the dielectric structure. The metal sheet is arranged with substantially uniform depth from the top surface of the dielectric structure. In some embodiments, at least one through hole formed on a projected area of at least one of the plurality of annular depressions on the metal sheet. The metal sheet is electrically floating with respect to the electrode. A thermal conductivity of the metal sheet is greater than a thermal conductivity of dielectric structure and a thermal conductivity of the electrode. The thermal conductivity of the metal sheet is greater than 400 W/mK. In some embodiments, the metal sheet is made of metal including a silver metal sheet having a thermal conductivity of 406 W/mK. A thickness of the metal sheet ranges from 10 nm to 100 nm.

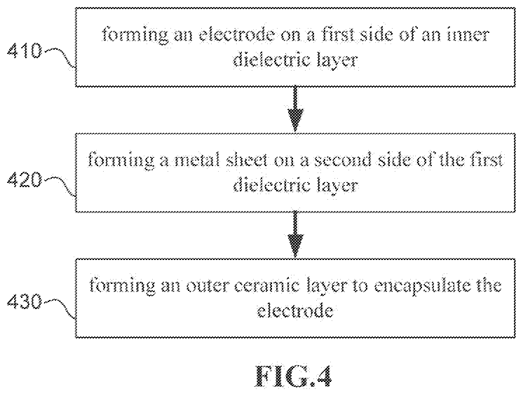

FIG. 4 illustrates a flowchart of a method of forming an ESC according to some other embodiment of the present disclosure. The method comprises forming an electrode on a first side of an inner dielectric layer (410), forming a metal sheet on a second side of the inner dielectric layer (420), and forming an outer dielectric layer to encapsulate the electrode, the metal sheet, and the inner dielectric layer (430). A dielectric structure is formed by the inner dielectric layer and the outer dielectric layer. In some embodiments the outer dielectric layer is formed through sintering wherein powdered ceramic are placed in a mold and encloses the inner dielectric layer, the metal sheet, and the electrode and applying high heat to the powdered ceramic to form a solid mass. In some embodiment, the metal sheet and the electrode are formed through lamination. In some embodiments, the mold used for forming the outer dielectric layer to form a plurality of annular protrusions of the dielectric structure and a plurality of interposing annular depressions defined there-between of the dielectric structure.

The metal sheet is a solid continuous metal sheet. In some embodiments, metal sheet is a flat metal sheet. In other embodiments, the metal sheet is an embossed sheet having protrusions and depressions conforming to the plurality of annular protrusions and the plurality of annular depressions of the top surface of the dielectric structure. The metal sheet is arranged with substantially uniform depth from the top surface of the dielectric structure. In some embodiments, at least one through hole formed on a projected area of at least one of the plurality of annular depressions on the metal sheet. The metal sheet is electrically floating with respect to the electrode. A thermal conductivity of the metal sheet is greater than a thermal conductivity of dielectric structure and a thermal conductivity of the electrode. The thermal conductivity of the metal sheet is greater than 400 W/mK. In some embodiments, the metal sheet is made of metal including a silver metal sheet having a thermal conductivity of 406 W/mK. A thickness of the metal sheet ranges from 10 nm to 100 nm.

Accordingly, one aspect of the instant disclosure provides an electrostatic chuck (ESC) that comprises a dielectric structure having a top surface; an electrode embedded in the dielectric structure; and a metal sheet embedded in the dielectric structure and disposed between the electrode and the top surface of the dielectric structure. In some embodiments, a thermal conductivity of the metal sheet is greater than a thermal conductivity of dielectric structure and a thermal conductivity of the electrode.

In some embodiments, the metal sheet is made of metal including a silver metal sheet.

In some embodiments, a thickness of the metal sheet ranges from 10 nm to 100 nm.

In some embodiments, the top surface of the dielectric structure comprises a plurality of annular protrusions and a plurality of interposing annular depressions defined there-between, and the metal sheet is an embossed sheet having protrusions and depressions conforming to the plurality of annular protrusions and the plurality of annular depressions of the top surface of the dielectric structure.

In some embodiments, the metal sheet is arranged with substantially uniform depth from the top surface of the dielectric structure.

In some embodiments, a distance between the metal sheet and a portion of the top surface of the dielectric structure closest to the metal sheet ranges from 10 μm to 200 μm.

In some embodiments, the top surface of the dielectric structure has a plurality of annular depressions and at least one through hole formed on a projected area of at least one of the plurality of annular depressions on the metal sheet.

In some embodiments, a thermal conductivity of the metal sheet is greater than 400 W/mK.

In some embodiments, the dielectric structure is made of at least one dielectric material including aluminum oxide, aluminum nitride, silicon carbide, carbon nitride, zirconia, yttria, and magnesia; and the electrode is made of at least one metal including copper, tungsten, aluminum, nickel, chrome, platinum, tin, molybdenum, magnesium, and palladium.

In some embodiments, the ESC further comprises a heating plate disposed under the dielectric structure and a bonding layer disposed between the heating plate and the dielectric structure.

In some embodiments, the bonding layer is made of at least one bonding material including a thermoplastic polyimide film (TPI), an epoxy thermal press bonding sheet, a low melting point metal, a low melting point metal alloy, and a eutectic alloy.

In some embodiments, the metal sheet is electrically floating with respect to the electrode.

Accordingly, another aspect of the instant disclosure provides a method of forming an electrostatic chuck (ESC) that comprises forming an electrode on a first dielectric layer; forming a second dielectric layer on the first dielectric layer, the second dielectric layer encapsulating the electrode; forming a metal sheet on the second dielectric layer; forming a third dielectric layer on the second dielectric layer, the third dielectric layer encapsulating the metal sheet; and forming a plurality of annular protrusions and a plurality of annular depressions interchanging from each other on the third dielectric layer. In some embodiments, a dielectric structure is formed by the first dielectric layer, the second dielectric layer, and the third dielectric layer and a thermal conductivity of the metal sheet is greater than a thermal conductivity of dielectric structure and a thermal conductivity of the electrode.

In some embodiments, the method further comprises etching the second dielectric layer to form a plurality of annular depressions. An embossed surface of the metal sheet conforms to the annular depressions of the second dielectric layer and the plurality of annular depressions of the top surface of the dielectric structure is formed with respect to the embossed surface of the metal sheet.

In some embodiments, the metal sheet is a silver metal sheet having a thickness ranging from 10 nm to 100 nm.

In some embodiments, the method further comprises forming a through hole through the dielectric structure and the metal sheet to form a coolant channel.

In some embodiments, the metal sheet is electrically floating with respect to the electrode.

Accordingly, another aspect of the instant disclosure provides a method of forming an electrostatic chuck (ESC) that comprises forming an electrode on a first side of an inner dielectric layer; forming a metal sheet on a second side of the inner dielectric layer; and forming an outer dielectric layer to encapsulate the electrode, the metal sheet, and the inner dielectric layer. In some embodiments, a dielectric structure is formed by the inner dielectric layer and the outer dielectric layer and a thermal conductivity of the metal sheet is greater than a thermal conductivity of dielectric structure and a thermal conductivity of the electrode.

In some embodiments, a surface of the outer dielectric layer has a plurality of annular depressions and an embossed surface of the metal sheet conforms to the annular depressions of the outer dielectric layer.

In some embodiments, the metal sheet is a silver metal sheet having a thickness ranging from 10 nm to 100 nm.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrostatic chuck (ESC), comprising:
a dielectric structure having a top surface;
an electrode embedded in the dielectric structure; and
a metal sheet embedded in the dielectric structure and disposed between the electrode and the top surface of the dielectric structure;
wherein a thermal conductivity of the metal sheet is greater than a thermal conductivity of dielectric structure and a thermal conductivity of the electrode.

2. The ESC of claim 1, wherein the metal sheet is made of metal including a silver metal sheet.

3. The ESC of claim 1, wherein a thickness of the metal sheet ranges from 10 nm to 100 nm.

4. The ESC of claim 1, wherein the top surface of the dielectric structure comprises a plurality of annular protrusions and a plurality of interposing annular depressions defined there-between, and the metal sheet is an embossed sheet having protrusions and depressions conforming to the plurality of annular protrusions and the plurality of annular depressions of the top surface of the dielectric structure.

5. The ESC of claim 4, wherein the metal sheet is arranged with substantially uniform depth from the top surface of the dielectric structure.

6. The ESC of claim 1, wherein a distance between the metal sheet and a portion of the top surface of the dielectric structure closest to the metal sheet ranges from 10 μm to 200 μm.

7. The ESC of claim 1, wherein the top surface of the dielectric structure has a plurality of annular depressions and at least one through hole formed on a projected area of at least one of the plurality of annular depressions on the metal sheet.

8. The ESC of claim 1, wherein a thermal conductivity of the metal sheet is greater than 400 W/mK.

9. The ESC of claim 1, wherein the dielectric structure is made of at least one dielectric material including aluminum oxide, aluminum nitride, silicon carbide, carbon nitride, zirconia, yttria, and magnesia; and the electrode is made of at least one metal including copper, tungsten, aluminum, nickel, chrome, platinum, tin, molybdenum, magnesium, and palladium.

10. The ESC of claim 1, further comprising:
a heating plate disposed under the dielectric structure; and
a bonding layer disposed between the heating plate and the dielectric structure.

11. The ESC of claim 10, wherein the bonding layer is made of at least one bonding material including a thermoplastic polyimide film (TPI), an epoxy thermal press bonding sheet, a low melting point metal, a low melting point metal alloy, and a eutectic alloy.

12. The ESC of claim 1, wherein the metal sheet is electrically floating with respect to the electrode.

13. A method of forming an electrostatic chuck (ESC), comprising:
forming an electrode on a first dielectric layer;
forming a second dielectric layer on the first dielectric layer, the second dielectric layer encapsulating the electrode;
forming a metal sheet on the second dielectric layer;
forming a third dielectric layer on the second dielectric layer, the third dielectric layer encapsulating the metal sheet; and
forming a plurality of annular protrusions and a plurality of annular depressions interchanging from each other on the third dielectric layer;
wherein a dielectric structure is formed by the first dielectric layer, the second dielectric layer, and the third dielectric layer and a thermal conductivity of the metal sheet is greater than a thermal conductivity of dielectric structure and a thermal conductivity of the electrode.

14. The method of claim 13, further comprising:
etching the second dielectric layer to form a plurality of annular depressions;
wherein an embossed surface of the metal sheet conforms to the annular depressions of the second dielectric layer and the plurality of annular depressions of a top surface of the dielectric structure is formed with respect to the embossed surface of the metal sheet.

15. The method of claim 13, wherein the metal sheet is a silver metal sheet having a thickness ranging from 10 nm to 100 nm.

16. The method of claim 13, further comprising:
forming a through hole through the dielectric structure and the metal sheet to form a coolant channel

17. The method of claim 13, wherein the metal sheet is electrically floating with respect to the electrode.

18. A method of forming an electrostatic chuck (ESC), comprising:
forming an electrode on a first side of an inner dielectric layer;
forming a metal sheet on a second side of the inner dielectric layer; and
forming an outer dielectric layer to encapsulate the electrode, the metal sheet, and the inner dielectric layer;
wherein a dielectric structure is formed by the inner dielectric layer and the outer dielectric layer and a thermal conductivity of the metal sheet is greater than a thermal conductivity of dielectric structure and a thermal conductivity of the electrode.

19. The method of claim 18, wherein a surface of the outer dielectric layer has a plurality of annular depressions and an embossed surface of the metal sheet conforms to the annular depressions of the outer dielectric layer.

20. The method of claim 18, wherein the metal sheet is a silver metal sheet having a thickness ranging from 10 nm to 100 nm.
